(19) United States
(12) Patent Application Publication
(10) Pub. No.: US 2010/0153826 A1
(43) Pub. Date: Jun. 17, 2010

(54) APPARATUS AND METHOD FOR TAIL BITING CONVOLUTIONAL ENCODING

(75) Inventors: Seong Chul CHO, Daejeon (KR); Hyung Jin Kim, Gyeryoung-si (KR); Dae Ho Kim, Daejeon (KR); Yeong Jin Kim, Daejeon (KR)

Correspondence Address: LAHIVE & COCKFIELD, LLP;FLOOR 30, SUITE 3000, ONE POST OFFICE SQUARE, BOSTON, MA, 02109, US

(73) Assignee: Electronics and Telecommunications Research Institute, Daejeon (KR)

(21) Appl. No.: 12/536,092

(22) Filed: Aug. 5, 2009

(30) Foreign Application Priority Data
Dec. 15, 2008 (KR) 10-2008-0127273

(51) Int. Cl. H03M 13/23; G06F 11/10

(52) U.S. Cl. 714/786; 714/E11.032

(57) ABSTRACT

Provided are an apparatus and a method for tail biting convolutional encoding. The apparatus includes a plurality of shift registers and at least one operator. The plurality of shift registers sequentially performs a shift operation on input bit-stream. The operator outputs an encoded bit-stream by performing convolutional encoding on an output of the shift register using a generator polynomial corresponding to a predetermined code rate. A transmission encoded bit-stream is created by replacing encoded data for a certain initial bit-stream of the encoded bit-stream with a bit-stream obtained by subsequently performing convolutional encoding on the initial bit-stream.

### CROSS-REFERENCE TO RELATED APPLICATIONS

This application claims priority under 35 U.S.C. §119 to Korean Patent Application No. 10-2008-0127273, filed on Dec. 15, 2008, in the Korean Intellectual Property Office, the disclosure of which is incorporated herein by reference in its entirety.

### TECHNICAL FIELD

The following disclosure relates to convolutional encoding, and in particular, to an apparatus and a method for tail biting convolutional encoding, which quickly performs tail biting convolutional encoding by affecting the result of information bit-stream coding with the result of initial bit coding.

### BACKGROUND

Recently, communication systems have been using various error correction schemes to correct transmission errors. A representative example of a related-art error correction scheme is a method that uses a convolutional code. The method is widely used because it can correct errors by adding additional bits without the needs of increasing transmission power and bandwidth.

According to a related-art convolutional encoding method, convolutional encoding is performed at a transmitting end, and Viterbi decoding is performed at a receiving end to restore information data and correct errors. Since the Viterbi decoding restores information data by inversely tracking a similar path, an initial value and a final value of a shift register at the transmitting end need to be maintained identically.

A related-art convolutional encoding method sets the initial value of the shift register to ‘0’ before convolutional encoding, and adds ‘0’s as many as the number of shift registers to the information data to perform convolution encoding. Therefore, a related-art convolutional encoding method can identically maintain the initial value and the final value of the shift registers at a transmitting end.

However, the above method has a limitation in that coding speed and transmission efficiency are reduced because ending bits corresponding to the number of shift registers are added for coding.

A tail biting convolutional encoding method has been proposed to solve the above limitation. In order to prevent a loss in transmission rate, the related-art tail biting convolutional encoding method sets the final bit value (corresponding to the number of shift registers of a transmission block) to an initial value of the shift registers.

A loss in transmission rate may be reduced in the related-art tail biting convolutional encoding. However, because the initial value of the shift register is set by extracting a certain number of bits after all data blocks to be transmitted are inputted, a temporary storage domain for the transmission data is required, and time loss occurs.

In particular, in case of transmission data is intermittently inputted by bit, inputting all bits from first to last takes considerable time to complete. And, encoding may not be initiated during the inputting.

### SUMMARY

In one aspect, a tail biting convolutional encoding apparatus includes: a plurality of shift registers sequentially performing a shift operation on input bit-stream; and at least one operator outputting an encoded bit-stream by performing convolutional encoding on an output of the shift registers using a generator polynomial corresponding to a predetermined code rate, wherein a transmission encoded bit-stream is created by replacing a certain amount of initial bit-stream of the encoded bit-stream with a bit-stream obtained by subsequently performing convolutional encoding on the initial bit-stream of the input bit-stream.

In another aspect, a tail biting convolutional encoding apparatus includes: a buffer storing initial L bits (L>0) of an input bit-stream; and an encoder including a plurality of shift registers, and performing tail biting convolutional encoding by performing convolutional encoding on input bit-stream and subsequently convolutional encoding the L bits stored in the buffer and by replace the initial portion of the convolutional-encoded input bit-stream with the subsequently convolutional-encoded L bits.

In other aspect, a tail biting convolutional encoding method includes: storing a certain initial bits of an inputted information bit-stream; creating a first encoded bit-stream by encoding the information bit-stream; creating a second encoded bit-stream by subsequently encoding the stored initial bits; and replacing a portion of the first encoded bit-stream with the second encoded bit-stream.

Other features and aspects will be apparent from the following detailed description, the drawings, and the claims.

### BRIEF DESCRIPTION OF THE DRAWINGS

FIG. 1 is a diagram illustrating a tail biting convolutional encoding apparatus according to an exemplary embodiment.

FIG. 2 is a diagram illustrating an encoder in FIG. 1.

FIG. 3 is a diagram illustrating a storage in FIG. 2.

FIG. 4 is a flowchart illustrating an exemplary tail biting convolutional encoding method.

### DETAILED DESCRIPTION OF EMBODIMENTS

Hereinafter, exemplary embodiments will be described in detail with reference to the accompanying drawings. Throughout the drawings and the detailed description, unless otherwise described, the same drawing reference numerals will be understood to refer to the same elements, features, and structures. The relative size and depiction of these elements may be exaggerated for clarity, illustration, and convenience. The following detailed description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. Also, descriptions of well-known functions and constructions may be omitted for increased clarity and conciseness.

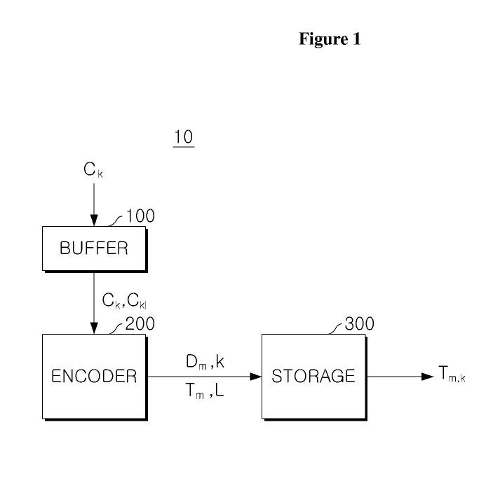

FIG. 1 is a diagram illustrating an exemplary tail biting convolutional encoding apparatus.

Referring to FIG. 1, an exemplary tail biting convolutional encoding apparatus 10 includes a buffer 100, an encoder 200, and a storage 300.

The buffer 100 stores initial L bits (L is the number of cells of the shift registers in the encoder 200) of information bit-stream consisting of n (1≦n) bits (Ck, 0≦k≦n−1) for a tail biting convolutional encoding.

The encoder 200 performs an encoding the information bit-stream from the moment when data is inputted into the buffer 100 without waiting for an input of the last bit. The encoder 200 performs the convolutional encoding of n information bit-stream consisting of n bits, included in an inputted data block, and stores the convolutional-coded bit-stream (D_{m,k}; 0≦k≦ the reciprocal of coding rate-1) in the storage 300. In this firstly enconding process, the initial value of the shift register do not care.

If the last bit is encoded, the encoder 200 sequentially performs convolutional encoding of an initial L bits stored in the buffer 100, and arranges the sub sequentially convolutional encoded initial L bits to the position of the initial L bits of the firstly convolutional-encoded bit-stream D_{m,k}, to generate a tail biting convolutional-encoded bit-stream T_{m,k}.

Here, the buffer 100 and the storage 300 may be storage media having different physical properties from each other, or occupy different portions of same storage medium. The buffer 100 and the storage 300 may have various configurations without being limited to the configuration illustrated in FIG. 1.

According to the embodiment, although data block to be transmitted is encoded from the moment of an input of the data block, the initial value of the shift register before the tail biting convolutional encoding and the final value of the shift register after the tail biting convolutional encoding are maintained identical. Also, time and clocks necessary for all bits to be inputted can be reduced, and a whole encoding processing can be simplified.

Then, the tail biting convolutional-encoded signal is modulated by a modulator (not shown) to be transmitted by a transmitter (not shown) through a communication channel.

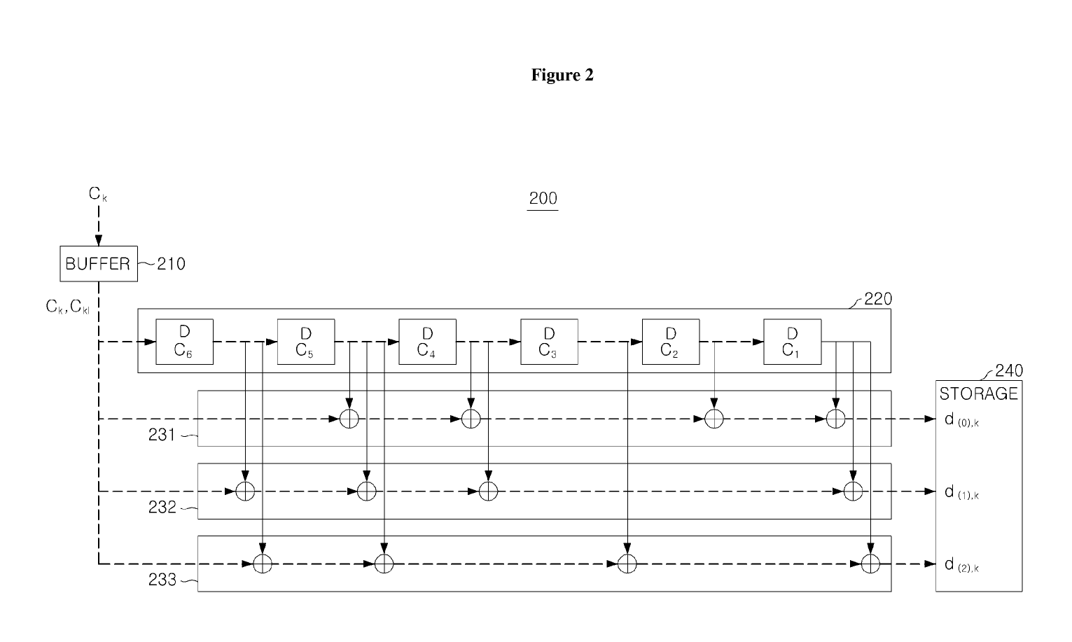

Hereinafter, the encoder 200 in FIG. 1 will be more fully described with reference to FIG. 2. Referring to FIG. 2, the encoder 200 includes L-bits shift registers 220, and operators 231, 232 and 233.

The shift registers 220 perform a shift operation on input bits. The operators 231, 232 and 233 are connected to each shift register 220 to operate an approprate code generator polynomial, and add two inputs to perform convolutional encoding and output a convolutional-encoded information bit.

For example, if the code rate is ⅓, the operators 231, 232 and 233 include three groups as described in FIG. 2. Each group is connected to shift register 220 to operate a generator polynomial according to the code rate of ⅓, and outputs n information bit-stream for a group, a total n×3 information convolutional-encoded bit-stream. In this case, the generator polynomial according to the code rate may be determined according to a related-art convolutional encoding. The detailed description thereof will be omitted herein because it is not directly related to the subject matter of the invention.

The encoder 200, as described in FIG. 1, is connected to a buffer 100 temporarily storing initial L bits of information bit-stream, and a storage 300 storing a convolutional-encoded information bits. Here, the buffer 100 and the storage 300 may be included in one storage medium.

The encoder 200 has the following differences from a related-art encoder. The encoder 200 sequentially encodes input bit-stream without initializing a register, and stores the encoded bit-stream in the storage 300. The encoder 200 encodes initial L bits stored in the buffer 100 subsequently to the last bit of the input bit-stream encoded, and writes the encoded result on the place of initial L bits of the encoded bit-stream stored in the storage 300.

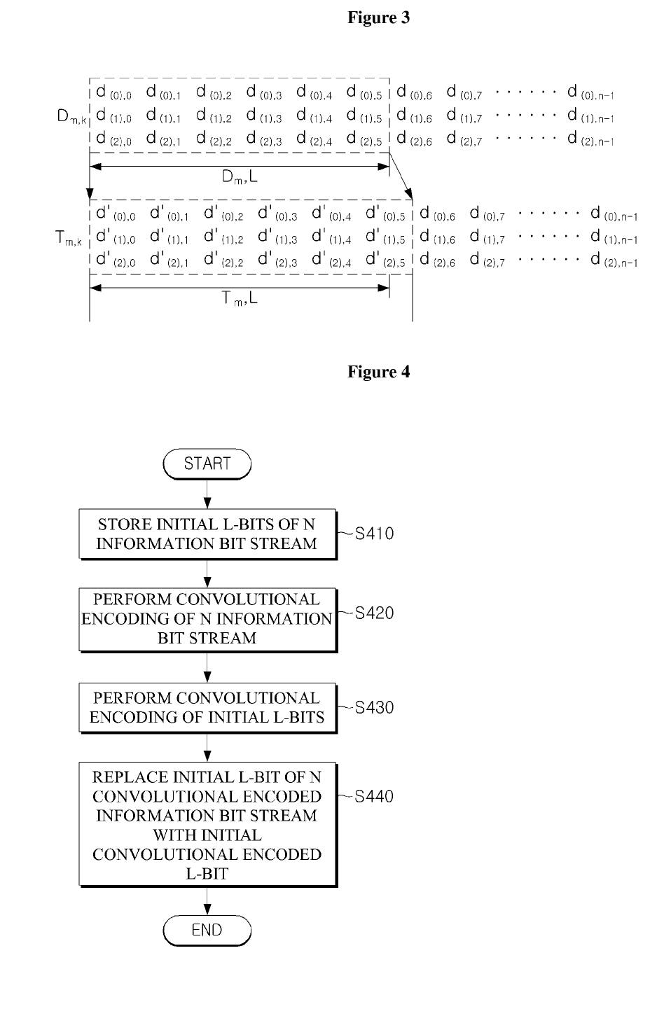

FIG. 3 is a diagram illustrating encoded bit-stream stored in a storage 300. Referring to FIG. 3, convolutional-encoded bit-stream D_{m,k} of n information bit-stream of a data block to be transmitted are stored in a storage 300.

An encoded bit-stream D_{m,L} with respect to initial L bits among the encoded bit-stream D_{m,k} is replaced with encoded bit-stream T_{m,L} with respect to initial L bits, thereby outputting tail biting convolutional-encoded bit-stream T_{m,k}.

Hereinafter, a tail biting convolutional encoding method will be described with reference to FIG. 4. FIG. 4 is a flowchart illustrating a tail biting convolutional encoding method according to an exemplary embodiment.

Referring to FIG. 4, in step S410, a tail biting convolutional encoding apparatus 10 stores initial L bits of information bit-stream. More specifically, the tail biting convolutional apparatus 10 determines L bits corresponding to a constraint length, and store bit-stream from the first bit to the Lth-bit of information bit-stream of a transmission data block.

In step S420, the tail biting convolutional apparatus 10 performs convolutional encoding on the information bit-stream constituting the transmission data block. More specifically, the tail biting convolutional apparatus 10 sequentially receives the information bit-stream to operate an appropriate generator polynomial for the convolutional encoding. Then, the tail biting convolutional apparatus 10 stores the convolutional-encoded bit-stream D_{m,k} in the storage 300. In this case, an initial value of a shift register need not be initialized because the shift register is not affected.

In step S430, the tail biting convolutional encoding apparatus 10 subsequently performs convolutional encoding on the initial L bits after the last bit of the information bit stream is encoded. More specifically, the tail biting convolutional encoding apparatus 10 performs the convolutional encoding of the initial L bits using the same generator polynomial as used in step S420.

In step S440, the tail biting convolutional encoding apparatus 10 writes the encoded bit-stream T_{m,L} obtained from step S430 on the convolutional-encoded bit-stream D_{m,L} domain with respect to initial L bits of the encoded bit-stream stored in the storage 300. That is, the bit-stream D_{m,L} of the encoded bit-stream D_{m,k} obtained from step S420 is replaced with the encoded bit-stream T_{m,L} obtained from step S430, thereby obtaining tail biting convolutional encoded bit-stream T_{m,k} to be transmitted.

In this case, the tail biting convolutional encoding apparatus 10 may replace the bit-stream D_{m,L} with the bit-stream T_{m,L} after storing the bit-stream T_{m,L} obtained from step S430, and may replace the bit-stream D_{m,L} with the bit-stream T_{m,L} while creating the bit-stream T_{m,L}.

Thus, the tail biting convolutional encoding apparatus 10 according to the embodiment can perform tail biting convolutional encoding while receiving the transmission data block. The tail biting convolutional encoding apparatus 10 can reduce a standby time, and can advance and simplify the encoding processing because the tail biting convolutional encoding apparatus 10 need not insert an additional bit to maintain equally an initial value and a final value of the shift register 210.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different scheme and/or replaced or supplemented by other components or their equivalents. Accordingly, other implementations are within the scope of the following claims.

What is claimed is:

1. A tail biting convolutional encoding apparatus comprising:
a plurality of shift registers sequentially performing a shift operation on input bit-stream; and
at least one operator outputting an encoded bit-stream by performing convolutional encoding on an output of the shift registers using a generator polynomial corresponding to a predetermined code rate,
wherein a transmission encoded bit-stream is created by replacing a certain initial bits of the encoded bit-stream with a bit-stream obtained by subsequently performing convolutional encoding on the initial bits of the input bit-stream.

2. The tail biting convolutional encoding apparatus of claim 1, wherein the initial bits comprise from the first bit to the Lth bit of the input bit-stream,
wherein L is the number of the cells of the shift register.

3. The tail biting convolutional encoding apparatus of claim 1, further comprising a storage storing the encoded bit-stream.

4. The tail biting convolutional encoding apparatus of claim 1, further comprising a buffer storing the initial bits of the input bit-stream.

5. A tail biting convolutional encoding apparatus comprising:
a buffer storing initial L bits (L>0) of an input bit-stream; and
an encoder comprising a plurality of shift registers, and convolutional encoding on the input bit-stream, subsequently convolutional encoding on the initial L bits stored in the buffer, and by replace a portion of the convolutional-encoded input bit-stream with the subsequently convolutional-encoded L bits.

6. The tail biting convolutional encoding apparatus of claim 5, wherein the buffer has a storage space storing bits corresponding to at least a constraint length.

7. The tail biting convolutional encoding apparatus of claim 5, wherein the encoder comprises:
a shift register sequentially shifting the input bit-stream; and
at least one operator performing convolutional encoding connected to the shift register to operate a certain generator polynomial, and adding two inputs to perform the convolutional encoding.

8. The tail biting convolutional encoding apparatus of claim 7, wherein a value of the shift register at a time of the tail biting convolutional encoding of the input bit-stream is identical to that at a time of immediately after the tail biting convolutional encoding.

9. The tail biting convolutional encoding apparatus of claim 7, wherein L is the number of cells of the shift register.

10. The tail biting convolutional encoding apparatus of claim 5, further comprising a storage storing the convolutional-encoded input bit-stream.

11. The tail biting convolutional encoding apparatus of claim 5, wherein the encoder changes the initial L bits of the convolutional-encoded input bit-stream into a result obtained by subsequently performing convolutional encoding on the L bits stored in the buffer.

12. A tail biting convolutional encoding method comprising:
storing a certain amount of initial bits of an inputted information bit-stream;
creating a firstly encoded bit-stream by encoding the information bit-stream;
creating a secondly encoded bit-stream by encoding the initial bits; and
replacing a portion of the firstly encoded bit-stream with the secondly encoded bit-stream.

13. The tail biting convolutional encoding method of claim 12, wherein the storing of a certain initial bits comprise:
determining a constraint length;
determining the number of cells of the shift registers corresponding to the constraint length; and
storing bits corresponding to the number of cells of the shift registers starting from the first bit of the information bit-stream.

14. The tail biting convolutional encoding method of claim 12, wherein the creating of a firstly encoded bit-stream comprises performing an operation by using a certain generator polynomial from the first bit to the last bit of the inputted information bit-stream.

15. The tail biting convolutional encoding method of claim 12, wherein the creating of a secondly encoded bit-stream comprises creating the secondly encoded bit-stream by sequentially operating the initial bits using a certain generator polynomial.

16. The tail biting convolutional encoding method of claim 14, wherein the creating of the firstly encoded bit-stream further comprises storing the firstly encoded bit-stream.

17. The tail biting convolutional encoding method of claim 15, wherein the replacing of a portion of the first encoded bit-stream comprises:
storing the secondly encoded bit-stream; and
replacing the initial bits of the firstly encoded bit-stream with the stored second encoded bit-stream.

18. The tail biting convolutional encoding method of claim 15, wherein, in the replacing of a portion of the firstly encoded bit-stream, the initial bits of the firstly encoded bit-stream is replaced with the secondly encoded bit-stream while the secondly encoded bit-stream is created.
